(19) United States
(12) Patent Application Publication
(10) Pub. No.: US 2013/0293069 A1
(43) Pub. Date: Nov. 7, 2013

(54) PIEZOELECTRIC POWER GENERATING APPARATUS

(71) Applicant: MURATA MANUFACTURING CO., LTD., Nagaokakyo-Shi (JP)

(72) Inventors: Hitoshi Sakaguchi, Nagaokakyo-Shi (JP); Chikahiro Horiguchi, Nagaokakyo-Shi (JP); Katsumi Fujimoto, Nagaokakyo-Shi (JP)

(21) Appl. No.: 13/933,529

(22) Filed: Jul. 2, 2013

Related U.S. Application Data
(63) Continuation of application No. PCT/JP2012/051413, filed on Jan. 24, 2012.

(30) Foreign Application Priority Data
Feb. 4, 2011 (JP) 2011-022330

(51) Int. Cl. H01L 41/053

(52) U.S. Cl. CPC H01L 41/053
USPC 310/348

(57) ABSTRACT

To achieve a piezoelectric power generating apparatus that is capable of both decreasing the natural vibration frequency and reducing the size and that has high power generation efficiency. A piezoelectric power generating apparatus including a power generating element having one end fixed to a supporting member and another end being a free end, and an excitation weight connected to the free end of the power generating element. The power generating element includes a vibration plate that is formed into a shape in which the vibration plate is folded back on the same plane between the one end and the other end and that includes multiple arm portions extending in parallel to each other. In addition, piezoelectric elements bonded to each arm portion of the vibration plate.

### CROSS REFERENCE TO RELATED APPLICATIONS

The present application is a continuation of PCT/JP2012/051413 filed Jan. 24, 2012, which claims priority to Japanese Patent Application No. 2011-022330, filed Feb. 4, 2011, the entire contents of each of which are incorporated herein by reference.

### FIELD OF THE INVENTION

The present invention relates to a piezoelectric power generating apparatus that converts mechanical energy into electrical energy by using piezoelectric effect to generate electric power.

### BACKGROUND OF THE INVENTION

Various piezoelectric power generating apparatuses that generate electric power using the piezoelectric effect have hitherto been proposed. Patent Document 1 discloses a piezoelectric power generating apparatus having a cantilever structure illustrated in FIG. 18. This piezoelectric power generating apparatus includes a power generating element 52 one end of which is fixed to a frame-shaped supporting member 51 and the other end of which is a free end; and an excitation weight 53 connected to the free end of the power generating element 52. The power generating element 52 has a unimorph structure in which a piezoelectric element 52b is bonded to one main face of a metal plate 52a and is wholly formed into a rectangular parallelepiped shape. When vertical acceleration is applied for the piezoelectric power generating apparatus, the action of the weight 53 excites free vibration at the power generating element 52 to generate electric charge in the piezoelectric element 52b by the piezoelectric effect. The generated electric charge is taken from electric charge collecting electrodes formed on the front and back faces of the piezoelectric element 52b.

In the case of the piezoelectric power generating apparatus having the above structure, bending stress occurring at the rectangular-parallelepiped-shaped power generating element 52 is almost zero at the free end, gradually increases toward a fixed end, and is maximized at the fixed end. The electric charge occurring at the power generating element 52 also has characteristics substantially proportional to those of the bending stress. Accordingly, the small amount of electric charge occurs near the free end of the power generating element 52 to make the power generation efficiency low.

In order to resolve the above problems, Patent Document 2 proposes a piezoelectric power generating apparatus using a power generating element having an isosceles triangular shape in a plan view. As illustrated in FIG. 19, in the piezoelectric power generating apparatus disclosed in Patent Document 2, the width of the power generating element is gradually decreased from the fixed end to the free end. This piezoelectric power generating apparatus includes a power generating element 61 one end of which is fixed to a supporting member 62 and the other end of which is the free end; and an excitation weight 63 connected to the free end of the power generating element 61. The power generating element 61 has a bimorph structure in which piezoelectric elements 61b are bonded to, both main faces of a metal plate 61a. In this piezoelectric power generating apparatus, the bending stress occurring at the power generating element 61 is equalized in the longitudinal direction to substantially equally generate the electric charge over the length of the piezoelectric elements 61b, thereby improving the power generation efficiency.

There are power generating apparatuses used in relatively low-frequency vibration regions. Such power generating apparatuses include power generating apparatuses using the vibration of automobiles or bicycles and power generating apparatuses using the vibration occurring when persons are walking. However, since the piezoelectric power generating apparatuses described in Patent Documents 1 and 2 each use the linear power generating element in which one end is the fixed end and the other end is the free end to which the weight is connected, there are problems in that it is difficult to lower the frequency and reduce the size. In other words, in order to lower the natural vibration frequency that is varied with the mass of the weight or a spring constant, it is necessary to decrease the thickness of the power generating element, to increase the length of the power generating element, or to increase the mass of the weight. It is difficult to freely vary the thickness of the power generating element and the mass of the weight because the power generating element is restricted in strength. Although it is possible to increase the length of the power generating element, the increase in the length of the power generating element is incompatible with the reduction in size. Since the decrease in the length of the power generating element for the reduction in size not only increases the natural vibration frequency but also decreases the volume of the piezoelectric element contributing the power generation by an amount corresponding to the decrease in the length of the power generating element, the amount of power generation is inevitably decreased.
Patent Document 1: Japanese Patent No. 3170965
Patent Document 2: Japanese Patent No. 3355971

### SUMMARY OF THE INVENTION

It is an object of the present invention to propose a piezoelectric power generating apparatus that is capable of both decreasing the natural vibration frequency and reducing the size and that has high power generation efficiency.

In order to achieve the above object, the present invention provides a piezoelectric power generating apparatus including a power generating element one end of which is fixed to a supporting member and the other end of which is a free end; and an excitation weight connected to the free end of the power generating element. The power generating element includes a vibration plate that includes multiple arm portions and folding portions connecting the arm portions and that is formed into a shape in which the vibration plate is folded back on the same plane between the one end and the other end; and piezoelectric elements bonded to one main face and/or the other main face of each arm portion of the vibration plate.

The present invention is characterized in that the power generating element having a shape in which the power generating element is folded back on the same plane between the one end and the other end is used instead of the linear power generating element. The power generating element includes the vibration plate and the piezoelectric elements bonded to the main faces of the vibration plate. The vibration plate includes the multiple arm portions and the folding portions connecting the arm portions, and the piezoelectric elements are bonded to the one main face and/or the other main face of each arm portion. Forming the power generating element into the shape in which the power generating element is folded back on the same plane allows the spring length from the fixed end to the free end to be lengthened, compared with the linear power generating element, to decrease the spring constant. Accordingly, it is possible to decrease the natural vibration frequency without decreasing the thickness of the power generating element and increasing the mass of the weight. In addition, since the power generating element is folded back on the same plane, the entire size is reduced to realize downsizing. Furthermore, since the space on the plane is effectively used, it is possible to increase the area of the piezoelectric elements contributing the power generation to improve the power generation efficiency.

The piezoelectric elements are bonded to the arm portions where the bending stress occurs in the vibration plate. A first reason for this is that, when the vibration plate having the shape in which the vibration plate is folded back on the same plane vibrates in a direction orthogonal to the plate thickness, the main vibration (bending vibration) mode occurs in the arm portions while the torsional mode is likely to occur in the folding portions and, thus, the bonding of the piezoelectric elements to the folding portions does not effectively contribute to the power generation. A second reason for this is that, since adjacent arm portions bend in opposite directions, the continuous bonding of the piezoelectric elements between adjacent arm portions causes the electric charges occurring at the arm portions to have different polarities to cancel the electric charges. Since the electric charge is taken from the arm portions where the main vibration mode occurs, the electromechanical coupling coefficient is improved to improve the power generation efficiency. The piezoelectric element may be bonded only to one main face of each arm portion or the piezoelectric elements may be bonded to both main faces of each arm portion. The unimorph power generating element is realized when the piezoelectric element is bonded only to one main face of each arm portion, and the bimorph power generating element is realized when the piezoelectric elements are bonded to both main faces of each arm portion. The piezoelectric elements may be separately bonded to the arm portions or the piezoelectric bodies may be continuously bonded to the main faces of the vibration plate and electrodes may be formed on the portions of the piezoelectric body corresponding to the respective arm portions to compose the separate piezoelectric elements. Accordingly, the piezoelectric elements in the present invention are not limited to the piezoelectric elements separately bonded to the respective arm portions. The piezoelectric elements may be made of piezoelectric ceramics or may be formed of organic piezoelectric bodies.

The power generating element preferably has a symmetric shape along a central axis CL parallel to a direction in which the arm portions extend. For example, the power generating element may be folded back from one end portion supported by the supporting member to the other end portion to which the weight is connected. However, since the power generating element has an asymmetric shape in this case, the torsional mode is likely to occur in the arm portions. The torsional mode inhibits the main vibration mode to decrease the electromechanical coupling coefficient. In contrast, forming the power generating element into a symmetric shape makes the torsional mode difficult to occur in the arm portions to efficiently cause the main vibration mode and increase the electromechanical coupling coefficient.

The supporting member may be arranged so as to oppose the weight with the power generating element sandwiched therebetween. The vibration plate may include a first arm portion one end of which is fixed to the supporting member and the other end of which extends toward the weight, a second arm portion one end of which is connected to the other end of the first arm portion via a first folding portion and the other end of which extends toward the supporting member, and a third arm portion one end of which is connected to the other end of the second arm portion via a second folding portion and the other end of which extends toward the weight and has the weight connected thereto. A pair of left and right first arm portions and a pair of left and right second arm portions may be provided with respect to the third arm portion. In this case, since the vibration plate has a symmetric shape with respect to the third arm portion and the two fixed ends are provided, the torsional mode in the arm portions is made substantially zero and the electromechanical coupling coefficient is improved. In addition, since the electric charge is collected from the five arm portions, the amount of power generation is increased.

It is preferred that the width of each first arm portion of the vibration plate be gradually decreased from the one end side to the other end side and the piezoelectric elements bonded to the main faces of the first arm portion have a shape similar to that of the first arm portion. Gradually decreasing the width of each first arm portion from the supporting member side to the weight side in the above manner allows the bending stress applied to the first arm portions to be equalized to improve the power generation efficiency.

It is preferred that the width of each second arm portion of the vibration plate be gradually increased from the one end side to the other end side and the piezoelectric elements bonded to the main faces of the second arm portion have a shape similar to that of the second arm portion. Although the second arm portions are intermediate arms via which the first arm portions are connected to the third arm portion, gradually increasing the width of each second arm portion from the weight side to the supporting member side allows the bending stress applied to the second arm portions to be equalized to improve the power generation efficiency.

It is preferred that the width of the third arm portion of the vibration plate be gradually decreased from the one end side to the other end side and the piezoelectric elements bonded to the main faces of the third arm portion have a shape similar to that of the third arm portion. Also in this case, gradually decreasing the width of the third arm portion from the supporting member side to the weight side in the above manner allows the bending stress applied to the third arm portion to be equalized to improve the power generation efficiency.

Although the exemplary structure in which the supporting member is arranged so as to oppose the weight with the power generating element sandwiched therebetween and the vibration plate includes the first to third arm portions is described above, the supporting member and the weight may be arranged at the same side with respect to the power generating element, the vibration plate may include a first arm portion one end of which is fixed to the supporting member, a second arm portion one end of which is connected to the weight, and a third folding portion and/or an intermediate arm portion via which the other end of the first arm portion is connected to the other end of the second arm portion, and a pair of left and right first arm portions and a pair of left and right third folding portions and/or intermediate arm portions may be provided with respect to the second arm portion. Also in this case, since the two fixed ends are provided and the vibration plate has a symmetric shape with respect to the second arm portion, it is possible to reduce the torsional mode in the arm portions to efficiently generate the electric power. In addition, since the supporting member and the weight are arranged at the same side, it is possible to further save the space.

When the piezoelectric elements are made of piezoelectric ceramics, the piezoelectric elements are preferably bonded to faces of the arm portions, to which compressive stress is applied when the weight is displaced downward. Acceleration of gravity is constantly applied on the power generating element in a vertical downward direction because of the effect of the gravity applied on the weight. Accordingly, the tensile stress is not applied on the power generating element unless an acceleration higher than the acceleration of gravity is applied on the weight in a vertical upward direction. Since the piezoelectric ceramics generally have higher mechanical strength for the compressive stress than that for the tensile stress, the bonding of the piezoelectric elements in the direction in which the compressive stress is applied when the weight is displaced downward allows the durability of the piezoelectric elements made of the piezoelectric ceramics to be increased.

As described above, according to the present invention, since the power generating element is formed into the shape in which the power generating element is folded back on the same plane, the spring length is increased, compared with the linear power generating element, and the entire size is reduced. Accordingly, it is possible to both decrease the natural vibration frequency and reduce the size. In addition, since the space in the plane is effectively used, the present invention has the advantages of increasing the area of the piezoelectric elements contributing to the power generation to improve the power generation efficiency.

### BRIEF DESCRIPTION OF THE DRAWINGS

FIG. 1 is a perspective view of a piezoelectric power generating apparatus according to a first embodiment of the present invention.

FIG. 2 is a plan view of the piezoelectric power generating apparatus according to the first embodiment of the present invention.

FIG. 3 is a side view illustrating a vibration mode when the piezoelectric power generating apparatus in FIG. 1 vibrates.

FIG. 4 is a circuit diagram when the piezoelectric power generating apparatus having a unimorph structure illustrated in FIG. 1 is connected to a rectification storage circuit.

FIG. 5 is a circuit diagram when a piezoelectric power generating apparatus having a bimorph structure is connected to the rectification storage circuit.

FIG. 6 is a perspective view of a piezoelectric power generating apparatus according to a second embodiment of the present invention.

FIG. 7 is a plan view of the piezoelectric power generating apparatus according to the second embodiment of the present invention.

FIG. 8 is a graph in which the electromechanical coupling coefficient of the piezoelectric power generating apparatus of the second embodiment and the electromechanical coupling coefficients of piezoelectric power generating apparatuses of modifications are compared with each other.

FIG. 9 includes plan views of the piezoelectric power generating apparatuses of the modifications.

FIG. 10 is a perspective view of a piezoelectric power generating apparatus according to a third embodiment of the present invention.

FIG. 11 is a plan view of the piezoelectric power generating apparatus according to the third embodiment of the present invention.

FIGS. 12(a) to 12(c) includes graphs in which the stress distribution of arm portions in the piezoelectric power generating apparatus of the first embodiment of the present invention is compared with the stress distribution of arm portions in the piezoelectric power generating apparatus of the third embodiment of the present invention.

FIG. 13 includes diagrams illustrating the positions of the arm portions where the stress distribution in FIG. 12 was measured.

FIG. 14 is a graph in which the electric power generated when the piezoelectric power generating apparatus of the second embodiment of the present invention resonates is compared with the electric power generated when the piezoelectric power generating apparatus of the third embodiment of the present invention resonates.

FIGS. 15(a) and 15(b) includes a perspective view and a plan view of a piezoelectric power generating apparatus according to a fourth embodiment of the present invention.

FIGS. 16(a) and 16(b) includes a plan view and a vibration mode diagram of a piezoelectric power generating apparatus according to a fifth embodiment of the present invention.

FIGS. 17(a) and 17(b) includes a plan view and a vibration mode diagram of a piezoelectric power generating apparatus according to a sixth embodiment of the present invention.

FIG. 18 is a perspective view of an exemplary piezoelectric power generating apparatus disclosed in Patent Document 1.

FIG. 19 is a perspective view of an exemplary piezoelectric power generating apparatus disclosed in Patent Document 2.

### DETAILED DESCRIPTION OF THE PREFERRED EMBODIMENTS OF THE INVENTION

### First Embodiment

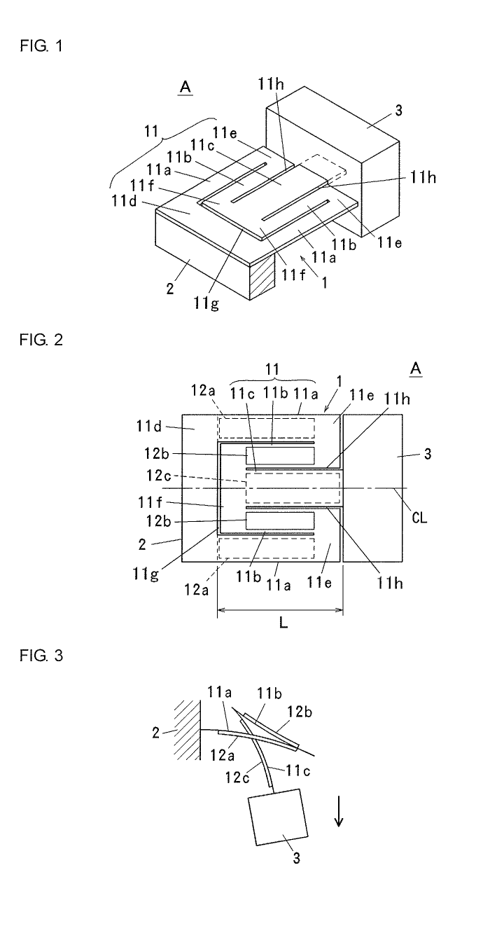

FIG. 1 to FIG. 3 illustrate a piezoelectric power generating apparatus according to a first embodiment of the present invention. A piezoelectric power generating apparatus A of the present embodiment includes a power generating element 1 one end of which is fixed to a supporting member 2 and the other end of which is a free end; and an excitation weight 3 connected to the free end of the power generating element 1. The supporting member 2 is composed of, for example, a case of an electronic mobile device, etc. or a fixed component fixed to the case. The weight 3 is composed of a mass body made of metal or the like. The weight 3 has a function to increase the amount of displacement of the power generating element 1. The power generating element 1 is capable of vertically bending and vibrating.

The power generating element 1 is composed of a vibration plate 11 formed of one metal plate having spring elasticity and piezoelectric elements 12a to 12c bonded to both main faces of the vibration plate 11. The piezoelectric elements 12a to 12c are omitted in FIG. 1. One end of the vibration plate 11 is fixed to an upper face of the supporting member 2. The other end of the vibration plate 11 is the free end and has the weight 3 mounted thereto. The vibration plate 11 has a structure in which the one end and the other end of the vibration plate 11 are on the same plane and the vibration plate 11 is folded back multiple times at positions between the one end and the other end. Accordingly, the vibration plate 11 of the present embodiment is formed in a meander pattern. Specifically, a U-shaped slit 11g in a plan view is formed between the one end and the other end of the vibration plate 11. Linear slits 11h are formed at both sides of the portion where the weight 3 is mounted at the other end side of the vibration plate 11. The vibration plate 11 includes first to third arm portions 11a to 11c extending in parallel to each other, a base portion 11d, and first and second folding portions 11e and 11f. The first to third arm portions 11a to 11c are separated from each other by the slits 11g and 11h formed between the first to third arm portions 11a to 11c. A pair of left and right first arm portions 11a and a pair of left and right second arm portions 11b are provided and the third arm portion 11c is provided at a central portion between the first arm portions 11a and the second arm portions 11b. Accordingly, the vibration plate 11 has a symmetric shape in a plan view along a central axis CL passing through the center line of the third arm portion 11c. Specifically, one end of each first arm portion 11a is connected to the wide base portion 11d, which is fixed to the supporting member 2. The first arm portions 11a each extend straight from the end portion at the supporting member 2 side to the weight 3 and are formed at a certain width over the entire length L. One end of each second arm portion 11b is connected to the other end of the corresponding first arm portion 11a via the corresponding first folding portion 11e. The second arm portions 11b each extend straight from the end portion at the weight 3 side to the supporting member 2 and are formed at a certain width over the entire length L. One end of the third arm portion 11c is connected to the other end of each second arm portion 11b via the corresponding second folding portion 11f. The third arm portion 11c extends straight from the end portion at the supporting member 2 side to the weight 3 and is formed at a certain width over the entire length L. The other end of the third arm portion 11c is the free end and has the weight 3 connected thereto.

The piezoelectric elements 12a to 12c are made of, for example, piezoelectric ceramics, such as lead zirconate titanate (PZT), having a certain width and are polarized in the thickness direction. The piezoelectric elements 12a to 12c each generate the electric charge caused by the bending stress of each arm portion. As illustrated in FIG. 2 and FIG. 3, in the present embodiment, the piezoelectric element 12a is bonded to the lower face of the first arm portion 11a, the piezoelectric element 12b is bonded to the upper face of the second arm portion 11b, and the piezoelectric element 12c is bonded to the lower face of the third arm portion 11c to establish the unimorph structure. The piezoelectric elements 12a to 12c each have a shape similar to that of the corresponding arm portion. The piezoelectric elements 12a to 12c may extend to portions over part of the first and second folding portions 11e and 11f, in addition to the provision on the main faces of the first to third arm portions 11a to 11c. However, it is desirable that the piezoelectric elements 12a to 12c be provided at portions on which uniform bending stress is applied.

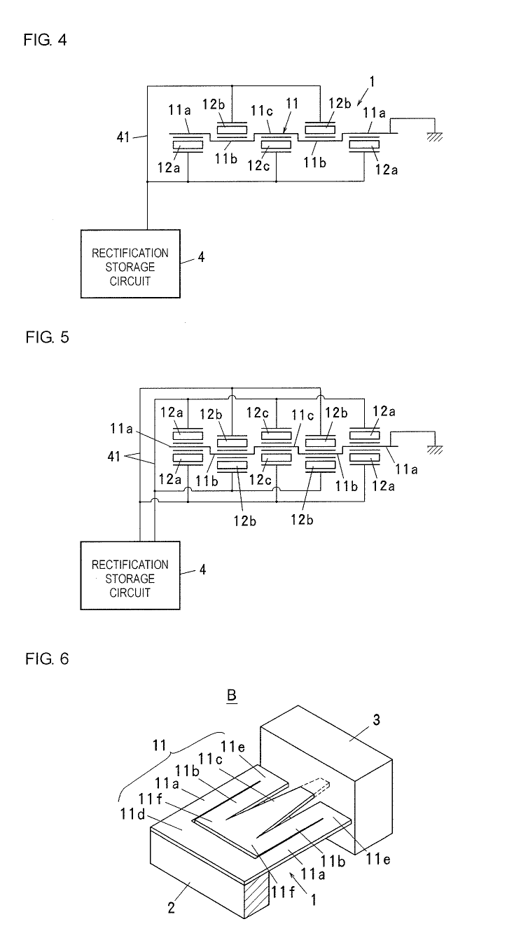

Electric charge collecting electrodes (not illustrated) are formed on the front and back faces of the piezoelectric elements 12a to 12c. The electric charge collecting electrode on one face of each of the piezoelectric elements 12a to 12c is electrically connected to the vibration plate 11. The electric charge collecting electrodes on the other faces of the piezoelectric elements 12a to 12c are connected to each other by a wiring line 41, as illustrated in FIG. 4, to be connected to a rectification storage circuit 4. The vibration plate 11 is grounded. The rectification storage circuit 4 has a function to rectify and smooth the output from each of the piezoelectric elements 12a to 12c and store the electric power. Since the rectification storage circuit 4 is commonly known, a detailed description of the rectification storage circuit 4 is omitted herein.

The operation of the piezoelectric power generating apparatus A having the above configuration will now be described. Upon exertion of vertical acceleration on the piezoelectric power generating apparatus A, the action of the weight 3 excites free vibration at the power generating element 1 to deform the power generating element 1 in a mode illustrated in FIG. 3. Accordingly, the bending stress is applied on the piezoelectric elements 12a to 12c to generate the electric charge proportional to the bending stress by the piezoelectric effect. For example, in a state in which the weight 3 is displaced downward in the manner illustrated in FIG. 3, the first arm portions 11a and the third arm portion 11c are deformed into an upward convex shape and the second arm portions 11b are deformed into a downward convex shape. Accordingly, compressive stress is applied on the piezoelectric elements 12a and 12c bonded to the lower faces of the first arm portions 11a and the third arm portion 11c, respectively, and on the piezoelectric elements 12b bonded to the upper faces of the second arm portions 11b. As a result, the electric charges occurring at the piezoelectric elements 12a to 12c have the same polarity and, thus, it is possible to efficiently accumulate the electrical energy that is generated in the rectification storage circuit 4. The mode illustrated in FIG. 3 is only an example of the deformation mode and is varied with, for example, the spring constant of each arm portion, the rigidity of the folding portions, and/or the mass of the weight.

Although the occurrence of the electric charge when the weight 3 is displaced downward is described in FIG. 3, the first arm portions 11a and the third arm portion 11c are deformed into a downward convex shape and the second arm portions 11b are deformed into an upward convex shape when the weight 3 is displaced upward. Accordingly, tensile stress is applied on the piezoelectric elements 12a and 12c bonded to the lower faces of the first arm portions 11a and the third arm portion 11c, respectively, and on the piezoelectric elements 12b bonded to the upper faces of the second arm portions 11b. In other words, although the electric charge having a reverse polarity with respect to the polarity in FIG. 3 occurs at the piezoelectric elements 12a to 12c, it is possible to easily accumulate the electrical energy that is generated in the rectification storage circuit 4 because the piezoelectric elements 12a to 12c have the same polarity. Acceleration of gravity is applied on the power generating element 1 in a vertical downward direction because of the effect of the gravity applied on the weight 3. Accordingly, the tensile stress is not applied on the power generating element 1 unless an acceleration higher than the acceleration of gravity is applied on the weight 3 in a vertical upward direction. Since the piezoelectric ceramics generally have higher mechanical strength for the compressive stress than that for the tensile stress, the bonding of the piezoelectric elements 12a to 12c in the direction in which the compressive stress is applied when the weight 3 is displaced downward allows the durability of the power generating element 1 to be increased.

The main natural vibration frequency of the piezoelectric power generating apparatus A is determined by a square root of a ratio between the spring constant of the vibration plate 11 and the mass of the weight 3. When the vibration plate 11 is formed into the shape of the present invention, it is possible to freely lengthen the spring length of the vibration plate 11 even when a distance L between the supporting member 2 and the weight 3 has a constant value to allow the spring constant to be arbitrarily adjusted. As a result, it is possible to realize the piezoelectric power generating apparatus having, for example, a low natural vibration frequency of several tens Hz.

Although the unimorph structure in which the piezoelectric elements 12a to 12c are bonded only to the one-side main faces of the first to third arm portions 11a to 11c, respectively, is adopted in the above embodiment, the bimorph structure in which the piezoelectric elements 12a to 12c are bonded to both main faces of the first to third arm portions 11a to 11c, respectively, may be adopted. In this case, alternately connecting the electric charge collecting electrodes of the piezoelectric elements 12a to 12c in opposite directions in a manner illustrated in FIG. 5 allows a larger amount of electric charge to be collected.

### Second Embodiment

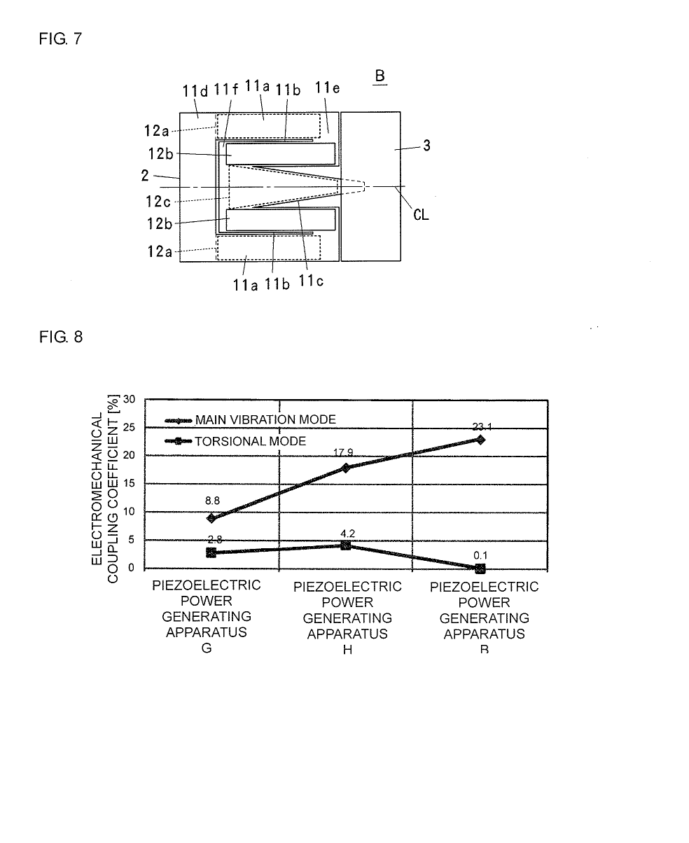

FIG. 6 and FIG. 7 illustrate a piezoelectric power generating apparatus according to a second embodiment of the present invention. The same reference numerals are used in the present embodiment to identify the same components described in the first embodiment. A description of such components is omitted herein. A piezoelectric power generating apparatus B of this embodiment differs from the piezoelectric power generating apparatus A of the first embodiment in that the width of the central third arm portion 11c is gradually decreased from one end side toward the supporting member 2 to the other end side connected to the weight 3 to be formed into an isosceles triangular shape in a plan view. The piezoelectric element 12c bonded to the lower face of the third arm portion 11c is similar to the third arm portion 11c to also be formed into an isosceles triangular shape in a plan view. The remaining structure of the piezoelectric power generating apparatus B of the second embodiment is the same as that of the piezoelectric power generating apparatus A of the first embodiment.

Since the third arm portion 11c and the piezoelectric element 12c are formed into the isosceles triangular shapes in a plan view in the second embodiment, a bending stress σ applied to the third arm portion 11c is equalized in the longitudinal direction and the amount of electric charge generated by the piezoelectric element 12c is also equalized in the longitudinal direction. Since the area of the piezoelectric element 12c of the second embodiment is smaller than that of the piezoelectric element 12c of the first embodiment, the volume of the piezoelectric element contributing the electric power generation is decreased while the stress applied to the piezoelectric element 12c is increased. As a result, the amount of power generation in the second embodiment is larger than that in the first embodiment. The reason for this will now be described.

The amount of electrical energy generated in the piezoelectric element is determined by a value resulting from division of the product of the square of the piezoelectric constant of the piezoelectric element, the square of the stress applied to the piezoelectric element, and the volume of the piezoelectric element by the permittivity of the piezoelectric element. In other words, an amount of power generation W is proportional to the product of the square of the stress σ applied to the piezoelectric element and a volume V of the piezoelectric element, as indicated in the following representation:

W∝σ²×V

Provided that the piezoelectric element has a constant thickness, the following representation is given because the volume V of the piezoelectric element is proportional to an area S of the piezoelectric element:

W∝σ²×S

Accordingly, it is effective to increase both of the stress σ applied to the piezoelectric element and the area S of the piezoelectric element in order to increase the amount of power generation. In particular, the stress σ has a larger effect on the amount of power generation, compared with the area S. For example, when the stress σ is made twice and the area S is made half, the amount of power generation W is made twice.

As described above, forming the third arm portion 11c and the piezoelectric element 12c into the isosceles triangular shapes in a plan view allows the amount of power generation to be increased, compared with the case in which the third arm portion 11c and the piezoelectric element 12c are formed into the rectangular shapes.

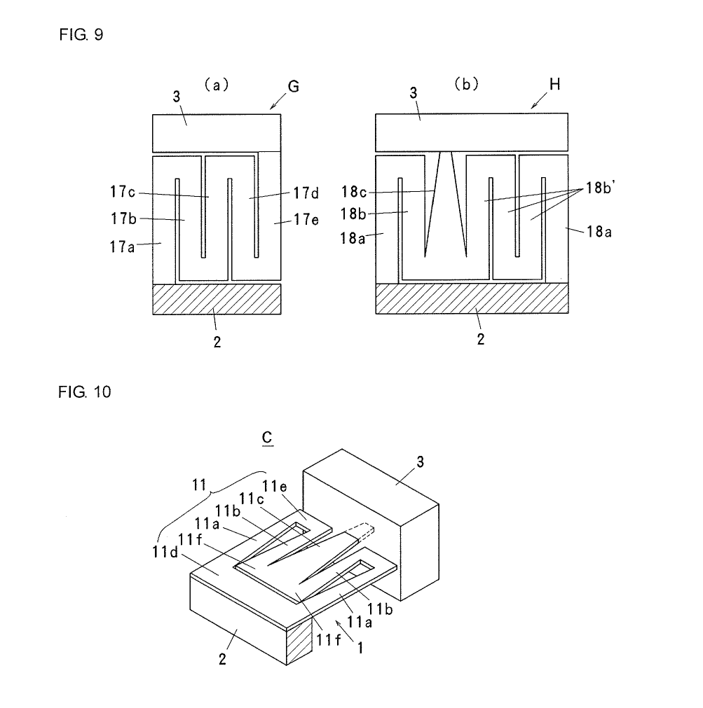

FIG. 8 is a graph in which the electromechanical coupling coefficient of the piezoelectric power generating apparatus B of the second embodiment and the electromechanical coupling coefficients of piezoelectric power generating apparatuses G and H of other embodiments (refer to FIG. 9) are compared with each other. The piezoelectric power generating apparatuses B, G, and H have the same resonant frequency (for example, 15 Hz). The piezoelectric power generating apparatus G includes first to fifth arm portions 17a to 17e connected in a meander pattern. One end of the first arm portion 17a is fixed to the supporting member 2, the first to fifth arm portions 17a to 17e are sequentially connected to each other via multiple folding portions, and the weight 3 is connected to the free end of the fifth arm portion 17e. All of the first to fifth arm portions 17a to 17e are formed into rectangular shapes in a plan view. The piezoelectric power generating apparatus H is similar to the piezoelectric power generating apparatus B of the second embodiment in that the piezoelectric power generating apparatus H includes a pair of first arm portions 18a one end of each of which is fixed to the supporting member 2 and a third arm portion 18c one end of which has the weight 3 connected thereto and which is formed into an isosceles triangular shape in a plan view. The piezoelectric power generating apparatus H is similar to the piezoelectric power generating apparatus B of the second embodiment in that a second arm portion 18b at one end side with respect to the third arm portion 18c is composed of only one arm portion while the piezoelectric power generating apparatus H differs from the piezoelectric power generating apparatus B of the second embodiment in that a second arm portion 18b′ at the other end side with respect to the third arm portion 18c is composed of three arm portions connected in a meander pattern. Each piezoelectric element (not illustrated) is bonded to one side of the corresponding arm portion.

Since the piezoelectric power generating apparatus G has an asymmetric shape, torsion is caused by the vibration of the weight 3 in the first to fifth arm portions 17a to 17e and a main vibration (bending vibration) mode is suppressed by a torsional mode. Accordingly, the piezoelectric power generating apparatus G has a low electromechanical coupling coefficient, as illustrated in FIG. 8. Although the electromechanical coupling coefficient of the piezoelectric power generating apparatus H is higher than that of the piezoelectric power generating apparatus G, the main vibration mode is suppressed by the torsional mode because the piezoelectric power generating apparatus H has an asymmetric shape. Accordingly, the piezoelectric power generating apparatus H has a low electromechanical coupling coefficient despite the fact that the number of arm portions in the piezoelectric power generating apparatus H is larger than that in the piezoelectric power generating apparatus B. In contrast, since only the main vibration mode occurs (the torsional mode is substantially zero) in the piezoelectric power generating apparatus B of the second embodiment, the piezoelectric power generating apparatus B has a very high electromechanical coupling coefficient. Since the electromechanical coupling coefficient correlate with the amount of power generation, it is possible for the piezoelectric power generating apparatus B to achieve superior power generation efficiency, compared with the piezoelectric power generating apparatuses G and H. However, it is possible to suppress the torsional mode by making the rigidity of the folding portions higher than that of the arm portions also in the piezoelectric power generating apparatuses G and H.

### Third Embodiment

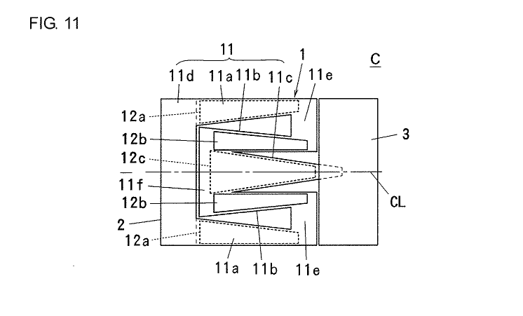

FIG. 10 and FIG. 11 illustrate a piezoelectric power generating apparatus according to a third embodiment of the present invention. The same reference numerals are used in the present embodiment to identify the same components described in the first embodiment. A description of such components is omitted herein. In a piezoelectric power generating apparatus C of this embodiment, the width of each first arm portion 11a is gradually decreased from the supporting member 2 side to the weight 3 side, the width of each second arm portion 11b is gradually increased from the weight 3 side to the supporting member 2 side, and the width of the third arm portion 11c is gradually decreased from the supporting member 2 side to the weight 3 side, as in the second embodiment. In other words, the piezoelectric power generating apparatus C of the third embodiment differs from the piezoelectric power generating apparatus A of the first embodiment in that the first to third arm portions 11a to 11c are formed into triangular shapes in a plan view. Accordingly, the vibration plate 11 has a symmetric shape along the central axis CL passing through the center line of the third arm portion 11c. The piezoelectric elements 12a to 12c bonded to the first to third arm portions 11a to 11c, respectively, each have a shape similar to that of the corresponding arm portion.

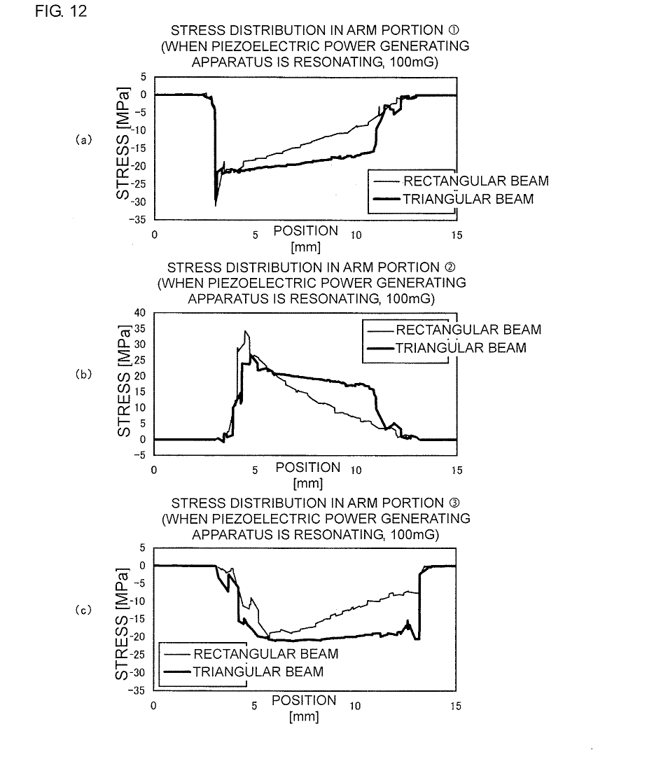

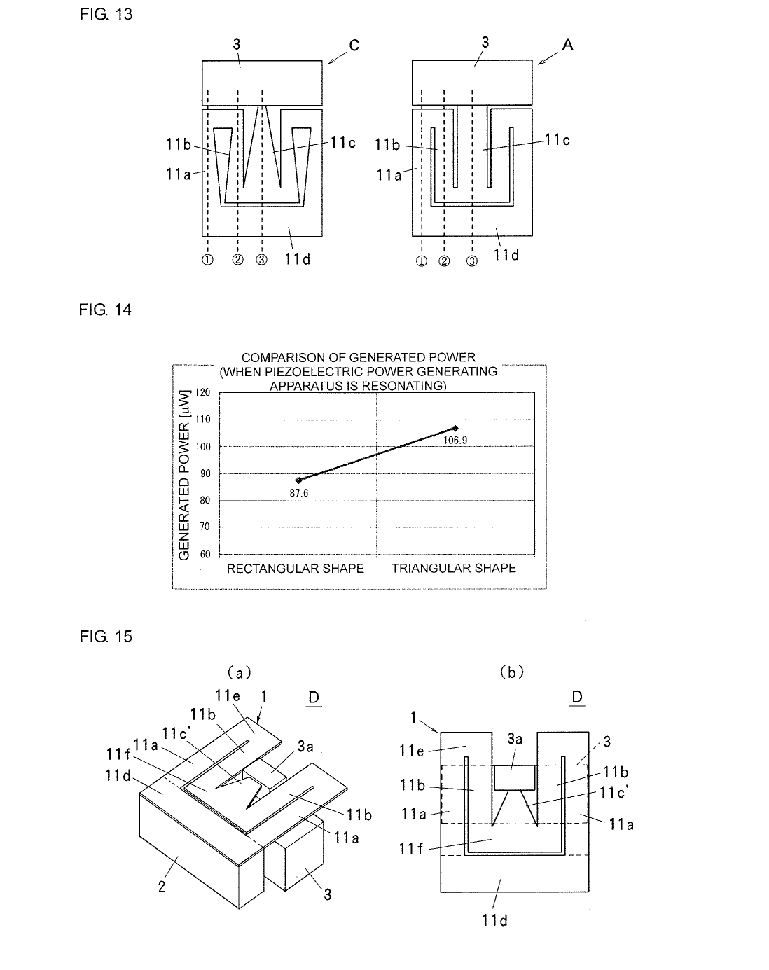

FIG. 12 includes graphs in which the stress distribution of the arm portions in the piezoelectric power generating apparatus A of the first embodiment is compared with the stress distribution of the arm portions in the piezoelectric power generating apparatus C of the third embodiment. The stress distribution was measured at the same positions of the respective arm portions, as illustrated by broken lines \textcircled{1} to \textcircled{3} in FIG. 13. The arm portions are provided within a range from 3 mm to 13 mm.

As illustrated in FIGS. 12(a) to 12(c), in the case of the first embodiment having the rectangular arm portions in a plan view, the stress distribution is not uniform and the stress at the free end side is substantially zero. In contrast, in the third embodiment having the triangular arm portions in a plan view, the stress distribution is uniform, the stress at each position is higher than that in the first embodiment having the rectangular arm portions, and the stress also occurs at the free end side. FIG. 12 indicates that the sum of the amounts of electrical energy generation in the arm portions in the piezoelectric power generating apparatus C of the third embodiment is larger than that in the piezoelectric power generating apparatus A of the first embodiment because the amount of power generation is proportional to a value (area) resulting from integration of the stress in the longitudinal direction.

FIG. 14 is a graph in which the electric power (the amount of power generation) generated when the piezoelectric power generating apparatus B of the second embodiment resonates is compared with the electric power (the amount of power generation) generated when the piezoelectric power generating apparatus C of the third embodiment resonates. The amount of power generation is calculated as the electric power consumed in a matching resistor that is connected on the basis of the voltage generated at the resonant frequency. FIG. 14 indicates that the amount of power generation in the case having the triangular arm portions in a plan view, as in the third embodiment, is larger than that in the case having the rectangular arm portions in a plan view (the central third arm portion has the triangular shape in a plan view), as in the second embodiment, by about 20%.

### Fourth Embodiment

FIG. 15 illustrates a piezoelectric power generating apparatus according to a fourth embodiment of the present invention. The same reference numerals are used in the present embodiment to identify the same components described in the first embodiment. A description of such components is omitted herein. In a piezoelectric power generating apparatus D of this embodiment, the length of a central third arm portion 11c′ is shorter than the lengths of the first and second arm portions 11a and 11b and the weight 3 is provided within the range of the entire length of the power generating element 1. A head 3a capable of passing between the second arm portions 11b protrudes above the weight 3 and the free end of the third arm portion 11c′ is connected to the head 3a. In this structure, the stress is reversed in the arm portions with respect to the position of the weight 3 and the electric charges of positive and negative polarities occur. In order to improve the power generation efficiency in such stress distribution, it is necessary to vary the polarization direction of the piezoelectric bodies in the arm portions in accordance with the stress distribution.

The stress distribution in the arm portions is determined by the positional relationship with the weight and it is necessary to provide the weight 3 at one end side of the power generating element 1 in order to cause the electric charges occurring in the arm portions to have the same polarity. The same applies to the supporting member 2.

### Fifth Embodiment

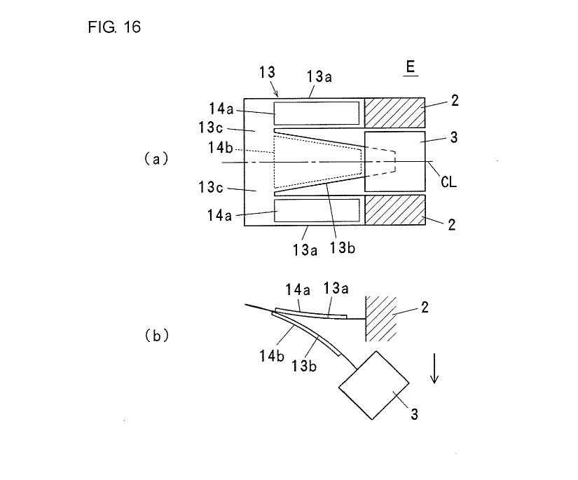

FIG. 16 illustrates a piezoelectric power generating apparatus according to a fifth embodiment of the present invention. The same reference numerals are used in the present embodiment to identify the same components described in the first embodiment. A description of such components is omitted herein. In a piezoelectric power generating apparatus E of this embodiment, the supporting member 2 and the weight 3 are arranged at the same side of the power generating element 1. Although the supporting member 2 is separated into two portions in this example, the portions of the supporting member 2 may be integrated with each other. A vibration plate 13 composing the power generating element 1 includes first arm portions 13a and a second arm portion 13b. The vibration plate 13 has a symmetric shape along the central axis CL passing through the center line of the second arm portion 13b. Specifically, the pair of the left and right first arm portions 13a is provided at both sides of the second arm portion 13b.

One end of each first arm portion 13a is fixed to the supporting member 2 and the other end of each first arm portion 13a linearly extends in a direction apart from the supporting member 2. Although the first arm portions 13a have a constant width in this example, the width of each first arm portion 13a may be gradually decreased from one end to the other end. One end of the second arm portion 13b is connected to the other end of each first arm portions 13a via a third folding portion 13c and the other end of the second arm portion 13b is connected to the weight 3. The width of the second arm portion 13b is gradually decreased from one end to the other end and the second arm portion 13b is formed into an isosceles triangular shape in a plan view. In this example, a piezoelectric element 14a is bonded to the upper face of each first arm portion 13a and a piezoelectric element 14b is bonded to the lower face of the second arm portion 13b. The piezoelectric element 14b bonded to the lower face of the second arm portion 13b is similar to the second arm portion 13b to also be formed into an isosceles triangular shape in a plan view.

In the piezoelectric power generating apparatus E, when the weight 3 is displaced downward, the vibration plate 13 vibrates in a mode in which each first arm portion 13a is deformed into a downward convex shape and the second arm portion 13b is deformed into an upward convex shape, as illustrated in FIG. 16(b). Accordingly, the compressive stress is applied to the piezoelectric elements 14a bonded to the upper faces of the first arm portions 13a and the piezoelectric element 14b bonded to the lower face of the second arm portion 13b and the electric charges occurring at the piezoelectric elements have the same polarity to efficiently generate the electric power. Also in this case, since the piezoelectric elements are bonded in the direction in which the compressive stress is applied when the weight 3 is displaced downward, the power generation efficiency is improved to increase the durability of the piezoelectric elements. The piezoelectric elements may be bonded to both faces of each first arm portions 13a and the second arm portion 13b to establish the bimorph structure.

### Sixth Embodiment

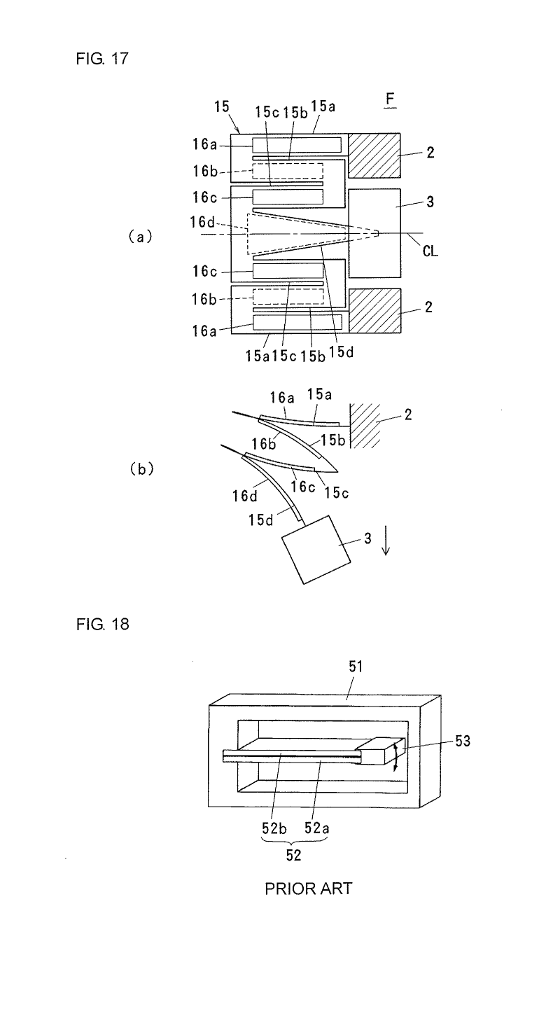

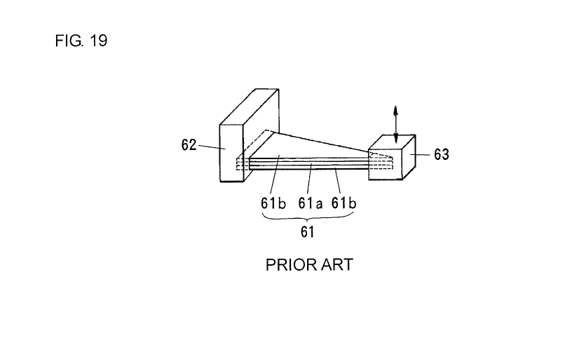

FIG. 17 illustrates a piezoelectric power generating apparatus according to a sixth embodiment of the present invention. The same reference numerals are used in the present embodiment to identify the same components described in the first embodiment. A description of such components is omitted herein. In a piezoelectric power generating apparatus F of this embodiment, the supporting member 2 and the weight 3 are arranged at the same side of the power generating element 1, as in the fifth embodiment. Although the supporting member 2 is separated into two portions in this example, the portions of the supporting member 2 may be integrated with each other. A vibration plate 15 composing the power generating element 1 includes first to fourth arm portions 15a to 15d that are parallel to each other. The arm portions are connected to each other via multiple folding portions. The vibration plate 15 has a symmetric shape in a plan view along the central axis CL passing through the center line of the fourth arm portion 15d. Specifically, the pair of the left and right first arm portions 15a, the pair of the left and right second arm portions 15b, and the pair of the left and right third arm portions 15c are provided at both sides of the fourth arm portion 15d. One end of each first arm portion 15a is fixed to the supporting member 2 and the weight 3 is connected to the tip of the fourth arm portion 15d. Although only the fourth arm portion 15d is formed into an isosceles triangular shape in a plan view in this example, the widths of the other arm portions may be gradually varied in accordance with the bending stress.

In this embodiment, a piezoelectric element 16a is bonded to the upper face of each first arm portion 15a, a piezoelectric element 16b is bonded to the lower face of each second arm portion 15b, a piezoelectric element 16c is bonded to the upper face of each third arm portion 15c, and a piezoelectric element 16d is bonded to the lower face of the fourth arm portion 15d. The piezoelectric element 16d bonded to the lower face of the fourth arm portion 15d is similar to the fourth arm portion 15d to also be formed into an isosceles triangular shape in a plan view.

In the piezoelectric power generating apparatus F, when the weight 3 is displaced downward, the first to fourth arm portions 15a to 15d are alternately deformed in opposite directions, as illustrated in FIG. 17(b). Accordingly, the compressive stress is applied to all the piezoelectric elements 16a to 16d and the electric charges occurring at the respective piezoelectric elements have the same polarity. Since the piezoelectric elements 16a to 16d are bonded in the direction in which the compressive stress is applied when the weight 3 is displaced downward, it is possible to increase the durability of the piezoelectric elements. Although the unimorph structure is described in the present embodiment, the piezoelectric elements may be bonded to the front and back faces of each of the first to fourth arm portions 15a to 15d to establish the bimorph structure.

The piezoelectric power generating apparatuses according to the present invention are not limited to the ones of the above embodiments and various modifications may be made. The vibration plate is not limited to the metal plate, and a resin plate having spring elasticity may be used as the vibration plate or the vibration plate may be made of a composite material containing metal and resin. The piezoelectric body is not limitedly made of the piezoelectric ceramics, and an organic piezoelectric body may be used as the piezoelectric body.

### REFERENCE SIGNS LIST

A to H piezoelectric power generating apparatus
1 power generating element
2 supporting member
3 weight
4 rectification storage circuit
11 vibration plate
11a first arm portion
11b second arm portion
11c, 11c′ third arm portion
11d base portion
11e first folding portion
11f second folding portion
12a to 12c piezoelectric element
13 vibration plate
13a first arm portion
13b second arm portion
13c third folding portion
14a, 14b piezoelectric element
15 vibration plate
15a to 15d first to fourth arm portions
16a to 16d piezoelectric element

1. A piezoelectric power generating apparatus comprising:
a vibration plate with a fixed end and a free end, the vibration plate including:
a plurality of arm portions juxtaposed to one another,
a plurality of folding portions that each connect at least two of the plurality of arm portions, and
a plurality of piezoelectric elements bonded to the plurality of arm portions, respectively;
a supporting member coupled to the fixed end of the vibration plate; and
an excitation weight coupled to the free end of the vibration plate.

2. The piezoelectric power generating apparatus according to claim 1, wherein the vibration plate is folded back on a same plane between the fixed end and the free end.

3. The piezoelectric power generating apparatus according to claim 1, wherein the fixed end is opposite the free end and the plurality of arm portions extend in a direction from the fixed end to the free end.

4. The piezoelectric power generating apparatus according to claim 3, wherein the vibration plate comprises a symmetric shape along a central axis CL that is parallel to the direction in which the arm portions extend.

5. The piezoelectric power generating apparatus according to claim 1, wherein the supporting member is configured to oppose the excitation weight with the vibration plate sandwiched therebetween.

6. The piezoelectric power generating apparatus according to claim 1, wherein the each of the plurality of folding portions extend in a direction substantially perpendicular to the plurality of arm portions.

7. The piezoelectric power generating apparatus according to claim 1,
wherein the supporting member and the weight are arranged at the same side of the vibration plate, and
wherein the plurality of arm portions includes a pair of first arm portions each having a first end fixed to the supporting member and a second end connected to at least one folding portion, and a second arm portion having a first end connected to the excitation weight and a second end connected to the at least one folding portion.

8. The piezoelectric power generating apparatus according to claim 1, wherein the plurality of piezoelectric elements are piezoelectric ceramics that are bonded to surfaces of the respective arm portions that undergo compressive stress when the excitation weight is displaced in a downward direction.

9. A piezoelectric power generating apparatus comprising:
a supporting member;
an excitation weight; and
a vibration plate including:
a first arm portion having a first end fixed to the supporting member and a second end extending towards the excitation weight,
a second arm portion having a first end connected to the second end of the first arm portion via a first folding portion and a second end extending towards the supporting member,
a third arm portion having a first end connected to the second end of the second arm portion via a second folding portion and a second end coupled to the excitation weight, and
a plurality of piezoelectric elements bonded to the first, second, and third arm portions, respectively.

10. The piezoelectric power generating apparatus according to claim 9, wherein the first arm portion comprises left and right first arm portions and the second arm portion comprises left and right second arm portions.

11. The piezoelectric power generating apparatus according to claim 10, wherein the left and right first arm portions gradually decrease in width from the first end to the second end of the first arm portion.

12. The piezoelectric power generating apparatus according to claim 11, wherein the respective piezoelectric elements bonded to the left and right first arm portions each have a shape that corresponds to the shape of the respective left and right first arm portions.

13. The piezoelectric power generating apparatus according to claim 10, wherein the left and right second arm portions gradually increase in width from the first end to the second end of the second arm portion.

14. The piezoelectric power generating apparatus according to claim 13, wherein the respective piezoelectric elements bonded to the left and right second arm portions each have a shape that corresponds to the shape of the respective left and right second arm portions.

15. The piezoelectric power generating apparatus according to claim 9, wherein the third arm portion gradually decreases in width from the first end to the second end of the third arm portion.

16. The piezoelectric power generating apparatus according to claim 15, wherein the piezoelectric element bonded to the third arm portion has a shape that corresponds to the shape of the third arm portion.

17. The piezoelectric power generating apparatus according to claim 9, wherein the plurality of piezoelectric elements are piezoelectric ceramics that are bonded to surfaces of the respective arm portions that undergo compressive stress when the excitation weight is displaced in a downward direction.

18. The piezoelectric power generating apparatus according to claim 9, wherein the third arm portion has a length shorter than lengths of both the first and second arm portions such that the excitation weight does not extend beyond the first folding portion.

19. The piezoelectric power generating apparatus according to claim 9,
wherein a first piezoelectric element of the plurality of piezoelectric elements is bonded to a lower surface of the first arm portion,
wherein a second piezoelectric element of the plurality of piezoelectric elements is bonded to an upper surface of the second arm portion,
wherein a third piezoelectric element of the plurality of piezoelectric elements is bonded to a lower surface of the third arm portion,
wherein respective electric charge collecting electrodes are disposed on upper and lower surface of the first, second and third piezoelectric elements, and
wherein each of the respective electric charge collecting electrodes are configured to electrically couple the vibration plate to a first input of a rectification storage circuit.

20. The piezoelectric power generating apparatus according to claim 19,
wherein fourth, fifth and sixth piezoelectric elements of the plurality of piezoelectric elements are bonded to upper surfaces of the first and third arm portions and a lower surface of the second arm portions, respectively,
wherein further respective electric charge collecting electrodes are disposed on upper and lower surface of the fourth, fifth and sixth piezoelectric elements, and
wherein each of the further respective electric charge collecting electrodes are configured to electrically couple the vibration plate to a second input of a rectification storage circuit.
